(19) United States
(12) Patent Application Publication
(10) Pub. No.: US 2008/0237705 A1
(43) Pub. Date: Oct. 2, 2008

(54) Ldmos Transistor

(75) Inventors: Stephan Jo Cecile Henri Theeuwen, Nijmegen (NL); Freerk Van Rijs, Nijmegen (NL); Petra C.A. Hammes, Ede (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/997,209

(22) PCT Filed: Aug. 2, 2006
(86) PCT No.: PCT/IB2006/052644

§ 371 Date: Jun. 3, 2008

(30) Foreign Application Priority Data
Aug. 10, 2005 (EP) 05107355.9

(51) Int. Cl. H01L 29/78

(52) U.S. Cl. 257/343; 257/E29.261

(57) ABSTRACT

The LDMOS transistor (1) of the invention comprises a substrate (2), a gate electrode (10), a substrate contact region (11), a source region (3), a channel region (4) and a drain region (5), which drain region (5) comprises a drain contact region (6) and drain extension region (7). The drain contact region (6) is electrically connected to a top metal layer (23), which extends over the drain extension region (7), with a distance (723) between the top metal layer (23) and the drain extension region (7) that is larger than 2μm. This way the area of the drain contact region (6) may be reduced and the RF power output efficiency of the LDMOS transistor (1) increased. In another embodiment the source region (3) is electrically connected to the substrate contact region (11) via a suicide layer (32) instead of a first metal layer (21), thereby reducing the capacitive coupling between the source region (3) and the drain region (5) and hence increasing the RF power output efficiency of the LDMOS transistor (1) further.

In base stations for personal communications systems (GSM, EDGE, W-CDMA), RF power amplifiers are the key components. For these power amplifiers, RF Laterally Diffused Metal Oxide Semiconductor, generally abbreviated as LDMOS, transistors are now the preferred choice of technology, because of their excellent high power capabilities, gain and linearity. To be able to meet the demands imposed by new communication standards, the performance of the LDMOS transistors with constantly shrinking dimensions is subject to continuous improvements.

In WO 2005/022645 an LDMOS transistor is disclosed, which comprises a source and a drain region in a semiconductor substrate, in which the source and the drain region are mutually connected through a channel region. The source region and the substrate are electrically connected through a first metal layer. The LDMOS transistor further comprises a gate electrode on the semiconductor substrate for influencing an electron distribution in the channel region. The drain region comprises a drain contact region and a drain extension region extending from the drain contact region towards the channel region. The drain contact region is electrically connected via a drain contact to a top metal layer, which extends only over the drain contact region and does not extend over the drain extension region. This way it is prevented that the top metal layer negatively influences the depletion of the drain extension region, because the series resistance of the drain extension region would become more voltage dependent if the top metal layer would extend over the drain extension region thereby reducing the performance of the LDMOS transistor. Furthermore, the top metal layer needs to have a high current capability, which results in a wide and thick top metal layer to be able to withstand a high current level without suffering from electromigration. Because the top metal layer is allowed to extend only over the drain contact region and because the top metal layer is wide enough to be able to withstand a high current level, the drain contact region occupies a relatively large area, which disadvantageously increases the total area occupied by the LDMOS transistor. Another disadvantage is that the relatively large area of the drain contact region results in a relatively large output capacitance of the LDMOS transistor. The output capacitance of the LDMOS transistor is, amongst others, determined by the capacitive coupling between the source region and the drain region, and comprises the drain extension region to source region capacitance and the drain contact region to source region capacitance. At a typical drain bias condition of 28V the drain extension region is almost completely depleted and hence the output capacitance of the LDMOS transistor is, at this typical bias condition, mainly determined by the drain contact region to source region capacitance. The relatively large output capacitance disadvantageously decreases the RF power output efficiency of the LDMOS transistor, which is defined as the RF output power divided by the DC input power of the LDMOS transistor.

It is an object of the invention to provide an LDMOS transistor with an improved RF power output efficiency. According to the invention, this object is achieved by providing an LDMOS transistor as claimed in claim 1.

The LDMOS transistor according to the invention comprises a source region and a drain region, both of a second semiconductor type, in a semiconductor substrate of a first semiconductor type, that are mutually connected through a channel region of the first semiconductor type. A gate electrode extends over the channel region and is able to influence an electron distribution in the channel region. The drain region comprises a drain contact region and a drain extension region, which drain extension region is adjacent to the channel region. The LDMOS transistor according to the invention further comprises a top metal layer which is electrically connected to the drain contact region through a drain contact and which extends over the drain extension region with a distance between the top metal layer and the drain extension region that is substantially larger than 2 μm. The invention is based on the insight that if the distance between the top metal layer and the drain extension region is such that the top metal layer hardly influences the depletion of the drain extension region, it becomes possible to allow the top metal layer to extend over the drain extension region without affecting the performance of the LDMOS transistor. Thereby it becomes possible to give the top layer any size needed to obtain the desired current capability, without a need to have an equally large size for the drain contact region. Furthermore, the area of the drain contact region and hence the output capacitance of the LDMOS transistor may be reduced in comparison with the prior art, because the area of the drain contact region does not need to be as large as the size of the top metal layer. The reduced output capacitance beneficially increases the RF power output efficiency of the LDMOS transistor.

Another advantage is that the reduction of the area of the drain contact region enables a reduction of the total area occupied by the LDMOS transistor.

Further, the distance between the top metal layer and the drain contact region is such that the top metal layer does not affect the feedback capacitance. The feedback capacitance is the capacitance between the drain region and the gate electrode. A shorter distance between the top metal layer and the drain contact region would increase the feedback capacitance thereby reducing the RF performance of the LDMOS transistor.

Further, the distance between the top metal layer and the drain extension region is such that the drain to source breakdown voltage of the LDMOS transistor at zero gate voltage (BVdss) is not affected by the top metal layer. A shorter distance between the top metal layer and the drain contact region would disadvantageously decrease the drain to source breakdown voltage of the LDMOS transistor.

In a first embodiment of the LDMOS transistor according to the invention, the distance between the top metal layer and the drain extension region is 5 μm. At this distance the influence of the top metal layer on the performance of the LDMOS transistor appeared to be sufficiently small.

In a second embodiment of the LDMOS transistor according to the invention, the electrical connection to the drain contact region via the drain contact further comprises at least one intermediate metal layer and at least one inter-metal contact between the intermediate metal layer and the top metal layer. The introduction of the at least one intermediate layer beneficially increases the distance between the top metal layer and the drain extension region and advantageously introduces a degree of freedom for the interconnection scheme of the LDMOS transistors and other devices on the IC (Integrated Circuit).

In a third embodiment of the LDMOS transistor according to the invention, the top metal layer comprises a mixture of Al and Cu. The fact that the dimensions of the top metal layer are not bound by the area of the drain contact region, allows for the use of a more common and cheaper metal material, as compared to Au. Because the mixture of Al and Cu material cannot withstand the same high current level as Au, the top metal layer has a larger width than the top metal layer of the prior art to enable the top metal layer to withstand the same high current level as the prior art without suffering from electromigration.

In a fourth embodiment of the LDMOS transistor according to the invention, the drain contact region of a first LDMOS transistor is common with the drain contact region of a second LDMOS transistor, which second LDMOS transistor is mirror-symmetrical with respect to the first LDMOS transistor. In this embodiment the advantage of the reduced area of the drain contact region is now shared by two LDMOS transistors, which will reduce the total area occupied by LDMOS transistors on the IC even further.

In a fifth embodiment the LDMOS transistor comprises a substrate contact region of the first semiconductor type, which adjoins the source region in which the substrate contact region and the source region are electrically connected via a silicide layer. The silicide layer is thinner than the first metal layer, which is used in the prior art to electrically connect the substrate contact region and the source region, thereby further reducing the feedback capacitance and hence further increasing the RF power output efficiency of the LDMOS transistor, because the dimensions of the silicide layer are smaller than those of the standard metal layer.

In a sixth embodiment the LDMOS transistor comprises a shield layer between the gate electrode and the drain contact region, wherein the shield layer extends over a part of the drain extension region. The introduction of the shield layer reduces the feedback capacitance between the gate electrode and the drain region, which is beneficial for the RF performance of the LDMOS transistor.

These and other aspects of the invention will be further elucidated and described with reference to the drawings, in which:

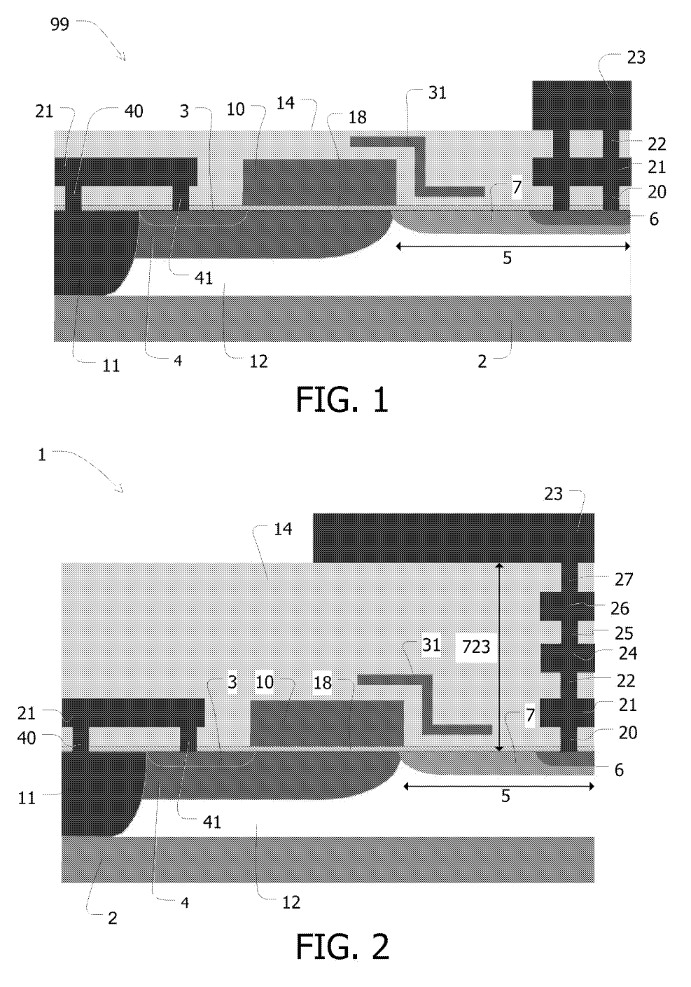

FIG. 1 shows a diagrammatical cross-sectional view of an LDMOS transistor according to the prior art;

FIG. 2 shows a diagrammatical cross-sectional view of an LDMOS transistor according to an embodiment of the invention;

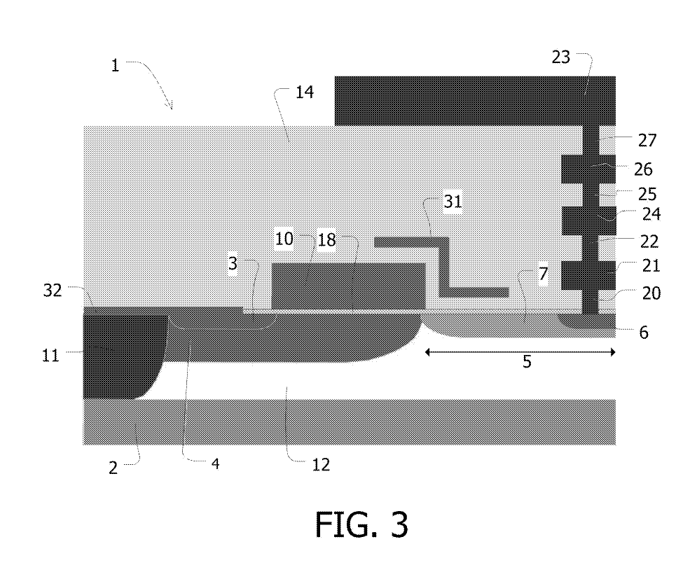

FIG. 3 shows a diagrammatical cross-sectional view of an LDMOS transistor according to a second embodiment of the invention; and

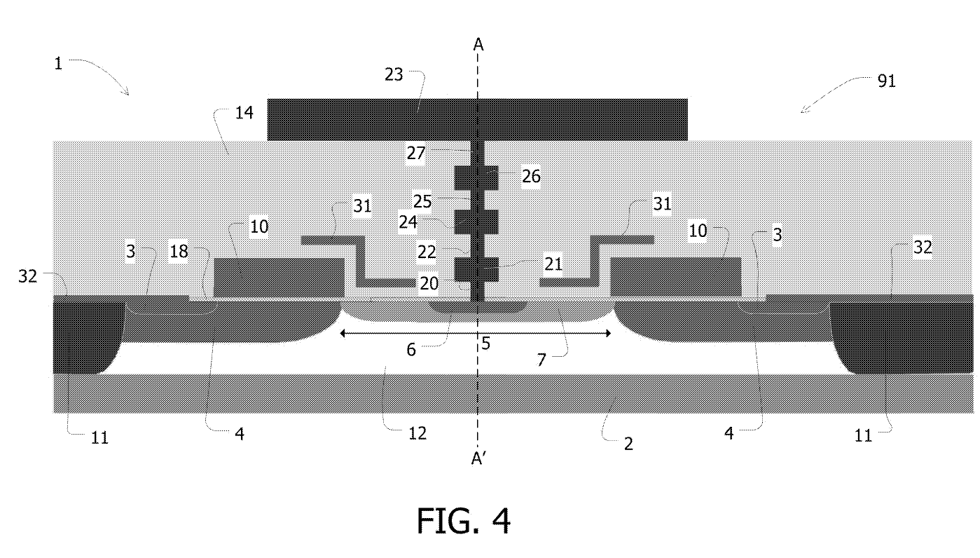

FIG. 4 shows a diagrammatical cross-sectional view of an LDMOS transistor according to a third embodiment of the invention.

The Figures are not drawn to scale. In general, identical components are denoted by the same reference numerals in the Figures.

FIG. 1 depicts a cross-sectional view of a conventional LDMOS transistor 99 according to the prior art, comprising a substrate 2 of a semiconductor material, in this case p-type silicon, on which a p-type epitaxial layer 12 is formed. The LDMOS transistor 99 further comprises an n-type source region 3, an n-type drain region 5 and a polysilicon gate electrode 10, which may optionally be provided with a silicide layer and which extends over a channel region 4, which is in this example a laterally diffused p-type region. The source region 3 and the drain region 5 are mutually connected through the channel region 4. A p-type substrate contact region 11 electrically connects to the substrate 2 and adjoins the source region 3 on a side opposite to the side, which adjoins the channel region 4. The channel region 4, the substrate contact region 11, the source region 3 and the drain region 5 are provided in the epitaxial layer 12. The gate electrode 10 is separated from the substrate 2 by a gate oxide layer 18, which for example comprises thermally grown silicon dioxide. The source region 3 is electrically connected to the substrate contact region 11 through a source contact 41, a first metal layer 21 and a substrate contact 40. Hence the source region 3 is, via the substrate contact region 11, electrically connected to the bottom surface of the substrate 2.

The drain region 5 comprises an n-type drain extension region 7, which accommodates the high voltage operation of the LDMOS transistor 99, and an n-type drain contact region 6. The drain extension region 7 has a lower doping level than the drain contact region 6 and is optimized for a maximum output power of the LDMOS transistor 99. It should be noted that the drain extension region 7 may also comprise multiple different-type doping levels, which improves the lifetime of the device.

The LDMOS transistor 99 further comprises a shield layer 31, which serves as a dummy gate electrode and improves the feedback capacitance. The shield layer 31 in this case extends over a portion of the gate electrode 10 and the drain extension region 7 and is separated from the gate electrode 10 by an insulation layer 14, which for example comprises a plasma oxide. The shield layer 31 is separated from the epitaxial layer 12, and hence the drain extension region 7, by the gate oxide layer 18 and the insulation layer 14. Due to the close proximity of the shield layer 31 to the gate electrode 10 and the drain extension region 7, the electric field distribution in the drain extension region 7 is improved, thereby reducing the feedback capacitance, which is beneficial for the RF performance.

The drain contact region 6 is used to electrically connect the drain region 5 to a first metal layer 21 and a top metal layer 23 via, respectively, a drain contact 20 and a first inter-metal contact 22. The distance between the top metal layer 21 and the drain extension region 7 is, in this example, 2 μm. It appeared that the performance of the LDMOS transistor 99, such as the source to drain breakdown voltage and the output capacitance, was negatively influenced when the top metal layer 21 extended over the drain extension region 7. Therefore, both the first metal layer 21 and the top metal layer 23 do not extend over the drain extension region 7 in order to prevent any negative influence of the metal layers on the performance of the LDMOS transistor 99. The top metal layer 23 has dimensions, for example the width and thickness, that are large enough to enable the top metal layer 23 to withstand a high current level without suffering from electromigration. Furthermore, the material of the top metal layer 23 comprises Au, which material is able to withstand a higher current level than other, more conventional, materials, such as Al and Cu, without suffering from electromigration. The area of the drain contact region 6 is relatively large, because the top metal layer 23 has a large width and is not allowed to extend over the drain extension region 7. The large area of the drain contact region 6 allows for applying a multiple of drain and first inter-metal contacts 20, 22.

FIG. 2 depicts a cross-sectional view of a first embodiment of an LDMOS transistor 1 according to the invention. The LDMOS transistor 1, similar to the LDMOS transistor 99 of the prior art, comprises the substrate 2, the substrate contact region 11, the epitaxial layer 12, the gate electrode 10, the shield layer 31, the insulation region 14, the gate oxide layer 18, the channel region 4, the source region 3 and the drain region 5, which comprises the drain contact region 6 and the drain extension region 7.

The main difference with the LDMOS transistor 99 of the prior art is that the top metal layer 23 of the LDMOS transistor 1 according to the invention extends over the drain extension region 7 with a distance 723, in this example, of 5 μm between the drain contact region 7 and the top metal layer 23. Another difference is that the top metal layer comprises a mixture of Al and Cu, which is a more common material used in IC technologies. Because this material cannot withstand the same high current level as Au, which material was applied in the LDMOS transistor 99 of the prior art, the top metal layer 23 has a larger width than the top metal layer of the LDMOS transistor 99 of the prior art to enable the top metal layer 23 to withstand the same high current level as the prior art without suffering from electromigration. Yet another difference with the LDMOS transistor 99 of the prior art is that in this case the drain contact region 6 is electrically connected to the top metal layer through the drain contact 20, the first metal layer 21, the first inter-metal contact 22, a second metal layer 24, a second inter-metal contact 25, a third metal layer 26 and a third inter-metal contact 27. This stack of metal layers and inter-metal contacts creates a distance 723 between the top metal layer 23 and the drain extension region 7 that is large enough to allow the top metal layer 23 to extend over the drain extension region 7 without influencing the performance of the LDMOS transistor. Furthermore the extra metal layers give an extra degree of freedom for designing a less area-consuming interconnection scheme of the LDMOS transistors and other devices on the IC.

The drain contact region 6 is electrically connected to the first metal layer 21 with one drain contact 20, which allows a substantive reduction of the area of the drain contact region 6. This area is then defined by the size of the drain contact 20 and the lithographic capabilities of the applied technology. The reduced area of the drain contact region 6 improves the RF power output efficiency of the LDMOS transistor 1, because of a reduction of the output capacitance.

FIG. 3 depicts a cross-sectional view of a second embodiment of the LDMOS transistor 1 according to the invention. In this embodiment the source region 3 and the substrate contact region 11 are electrically connected through a silicide layer 32, which is thinner than the first metal layer 21 and which reduces the capacitive coupling between the source region 3 and the drain region 5. Hence the output capacitance is reduced with a corresponding further increase of the RF power output efficiency of the LDMOS transistor 1.

FIG. 4 depicts a cross-sectional view of a third embodiment of the LDMOS transistor 1 according to the invention in which the drain contact region 6 of the LDMOS transistor 1 is common with the drain contact region 6 of a second LDMOS transistor 91, which second LDMOS transistor 91 is mirror-symmetrical with respect to the LDMOS transistor 1 along the axis A-A′. Furthermore, two LDMOS transistors 1 and 91 now share the advantage of the reduced area of the drain contact region 6. This way the area occupied by the LDMOS transistor 1 and the second LDMOS transistor 91 is even smaller than the case when the LDMOS transistor 1 and the LDMOS transistor 91 each would have their own separate drain contact region 6.

Results of measurements performed on the LDMOS transistor 1 show an increase of the RF power output efficiency of around 4 percent point, depending on the measurement conditions, compared to the LDMOS transistor 99 of the prior art. Furthermore, it is shown that the output capacitance is decreased by around 15%, depending on the measurement conditions, compared to the LDMOS transistor 99 of the prior art.

In summary, the LDMOS transistor of the invention comprises a substrate, a gate electrode, a substrate contact region, a source region, a channel region and a drain region, which drain region comprises a drain contact region and a drain extension region. The drain contact region is electrically connected to a top metal layer, which extends over the drain extension region, with a distance between the top metal layer and the drain extension region that is larger than 2 μm. This way the area of the drain contact region may be reduced and the RF power output efficiency of the LDMOS transistor increased. In another embodiment the source region is electrically connected to the substrate contact region via a silicide layer instead of a first metal layer, thereby reducing the capacitive coupling between the source region and the drain region and hence increasing the RF power output efficiency of the LDMOS transistor further.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. An LDMOS transistor provided in a semiconductor substrate of a first semiconductor type, the LDMOS transistor comprising a source region and a drain region both of a second semiconductor type and being mutually connected through a channel region over which a gate electrode extends, the drain region comprising a drain contact region and a drain extension region extending from the channel region towards the drain contact region (6), wherein the drain contact region is electrically connected to a top metal layer via a drain contact, characterized in that the top metal layer extends over at least a part of the drain extension region with a distance between the top metal layer and the drain extension region that is larger than 2 μm.

2. An LDMOS transistor as claimed in claim 1 wherein the distance between the top metal and the drain extension region is 5 μm.

3. An LDMOS transistor as claimed in claim 1 wherein the drain contact and the top metal layer are electrically connected through at least one intermediate metal layer and at least one inter-metal contact.

4. An LDMOS transistors as claimed in claim 1 wherein the top metal layer comprises a mixture of Al and Cu.

5. An LDMOS transistor as claimed in claim 1 wherein the drain contact region is electrically connected to the top metal layering with one drain contact.

6. An LDMOS transistors as claimed in claim 1 wherein the drain contact region of the LDMOS transistor is common with the drain contact region of a second LDMOS transistor, which second LDMOS transistor is mirror-symmetrical with respect to the LDMOS transistor.

7. An LDMOS transistor as claimed in claim 1 wherein the LDMOS transistor further comprises a substrate contact region of the first semiconductor type, which adjoins the source region at a side opposite to the side that adjoins the channel region, and in which the substrate contact region and the source region are electrically connected via a silicide layer.

8. An LDMOS transistor as claimed in claim 1 further comprising a shield layer between the gate electrode and the drain contact region, the shield layer covering a part of the drain extension region.
